(19) United States
(12) Patent Application Publication
(10) Pub. No.: US 2011/0081617 A1
(43) Pub. Date: Apr. 7, 2011

(54) INTEGRATED LITHOGRAPHY EQUIPMENT AND LITHOGRAPHY PROCESS THEREOF

(76) Inventors: Chia-Fang Lin, Hsinchu City (TW); Kok-Leng Loh, Singapore (SG); Shu-Ping Fang, Hsinchu City (TW)

(21) Appl. No.: 12/573,158

(22) Filed: Oct. 5, 2009

(51) Int. Cl. G03F 7/20; G03B 27/42; G03B 27/52

(52) U.S. Cl. 430/325; 355/53; 355/30

(57) ABSTRACT

An integrated lithography equipment is disclosed. The equipment includes an input/output area for loading at least one wafer, a coating a developing area for performing coating and developing processes on the wafer, an exposure processing area for exposing the wafer, and an idle and transport area disposed between the coating and developing area and the exposure processing area for isothermally or adiabatically transferring wafers between the coating and developing area and the exposure processing area and holding wafers isothermally or adiabatically.

### BACKGROUND OF THE INVENTION

1. Field of the Invention

The invention relates to an integrated lithography equipment, more particularly, to a lithography equipment capable of maintaining the temperature of wafers as the wafers

2. Description of the Prior Art

Lithography is a critical step in semiconductor fabrication to transfer the layout pattern of integrated circuits onto semiconductor wafers. Preferably, the pattern of a photomask is transferred through exposure and development processes to the photoresist formed on surface of the semiconductor wafers. In current lithography, after the wafers are coated with photoresist in the coating area of lithography equipment, a pre-baking is conducted by using a temperature between 90° C. to 120° C. to transform the liquid-state photoresist into a solid-state film, which enhances the adhesion between the photoresist and the wafer. After the pre-baking process, the wafers are idled and cooled in an idle area to approximately room temperature before an exposure process is performed on the wafers. As the cooling process takes a certain amount of time, an idle period is consumed in the lithography equipment before the wafers are being transferred to the exposure area.

### SUMMARY OF THE INVENTION

It is an objective of the present invention to provide an integrated lithography equipment and related lithography process to improve the overlay accuracy of the current lithography process.

The lithography equipment includes an input/output area for loading at least one wafer, a coating a developing area for performing coating and developing processes on the wafer, an exposure processing area for exposing the wafer, and an idle and transport area disposed between the coating and developing area and the exposure processing area for isothermally or adiabatically transferring wafers between the coating and developing area and the exposure processing area and holding wafers isothermally or adiabatically.

The lithography process includes the steps of: providing a wafer; performing a first process to the wafer in a first processing area to obtain a processed wafer; and idling or transporting the processed wafer isothermally or adiabatically in an idle and transport area to a second processing area for a second process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a block diagram of an integrated lithography equipment according to a first embodiment of the present invention.

FIG. 2 illustrates an actual top view of the integrated lithography equipment of FIG. 1.

FIG. 3 illustrates a perspective view of an isolating system according to an embodiment of the present invention.

FIG. 4 illustrates a block diagram of disposing a heating/cooling system onto an electronic rack or wafer cassette according to an embodiment of the present invention.

FIG. 5 illustrates a block diagram of disposing a heating/cooling system in an electronic rack or wafer cassette according to an embodiment of the present invention.

FIG. 6 illustrates a block diagram of an integrated lithography equipment according to another embodiment of the present invention.

FIG. 7 illustrates a block diagram of an integrated lithography equipment according to an embodiment of the present invention.

### DETAILED DESCRIPTION

The interior of a lithography equipment is typically filled with numerous electronic devices therein, including printed circuits board and functional modules utilized for controlling the equipment as well as other connecting wires. As the wafers are typically placed on top of the lithography equipment and on top of these devices during the idling period, heat generated by these devices would easily disrupt the idled wafers. For instance, heat could evaporate solvents in the photoresist directly or cause expansion or bending of the wafers. This results in serious misalignment during the pattern transfer process as well as affects the overlay accuracy.

Overlay accuracy is a key factor to control lithographic technology. Most of electric circuit patterns are formed by transferring the patterns of masks to photoresists in the lithographic processes and later transferring the patterns of photoresists to the material layers of a wafer in a subsequent etching process. Therefore, the patterns of the masks must be disposed in exact positions in every etching process for forming electric circuit patterns in each material layer. Otherwise, the electric circuit pattern in one material layer may not correspond with the underlying electric circuit pattern and failure of the fabricated electric circuits would result. It has been found that during the measurement for overlay accuracy, mis-alignment often results in vector field distribution pattern and also affects gate length and contact resistance of high voltage device substantially. Hence, how to effectively control the overlay accuracy in lithography process has become an important task.

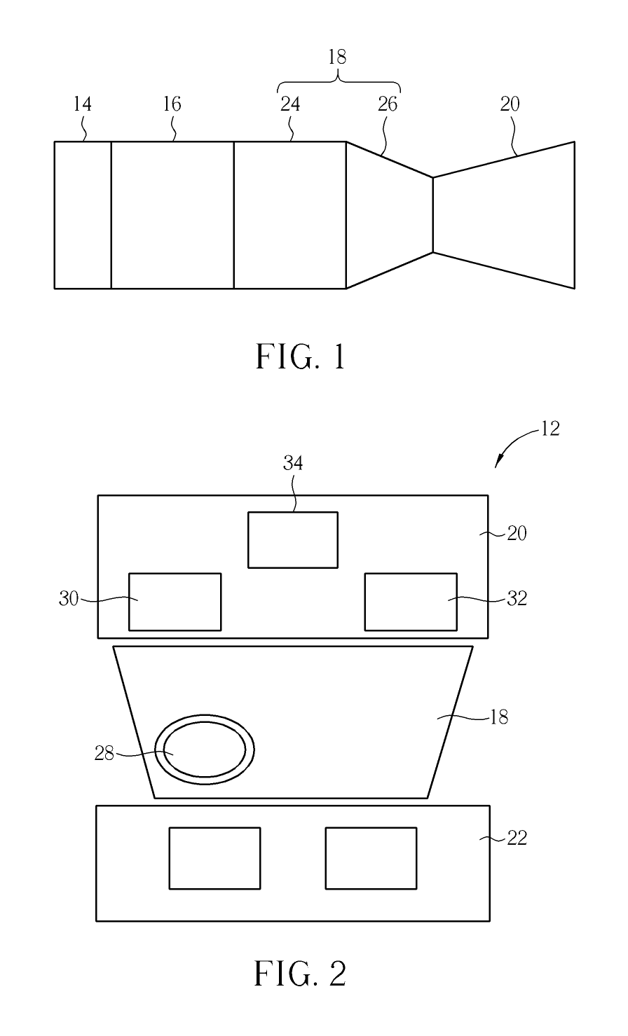

Referring to FIGS. 1-2, FIG. 1 illustrates a block diagram of an integrated lithography equipment according to a first embodiment of the present invention and FIG. 2 illustrates an actual top view of the integrated lithography equipment 12. As shown in the figures, the integrated lithography equipment 12 includes an input/output area 14, a coating and developing area 16, an idle and transport area 18, and an exposure processing area 20. The input/output area 14 is positioned relative to the entrance of the integrated lithography equipment 12 and this area 14 accommodates the wafers ready to be coated with photoresist and wafers that have already been processed through photo-lithography. The coating and developing area 16 is located right after the input/output area 14, which could include a plurality of tracks 22 for transporting the wafers. Wafers after being passed from the input/output area 14 to the coating and developing area 16 will undergo a series of coating and soft baking processes.

The idle and transport area 18 is located between the coating and developing area 16 and the exposure processing area 20. A wafer chuck 28 is disposed on the idle and transport area 18 for supporting wafers ready to be entered into the exposure processing area 20 or transported out from the exposure processing area 20 for developing process. In this embodiment, the idle and transport area 18 is further divided into a track idle area 24 and an exposure idle area 26, in which the track idle area 24 is located adjacent to the coating and developing area 16 and the exposure idle area 26 is adjacent to the exposure processing area 20.

As shown in FIG. 2, the exposure processing area 20 includes a loading inlet 30, an unloading inlet 32, and an exposure inlet 34. The loading inlet 30 and the unloading inlet 32 are located adjacent to the idle and transport area 18 such that the wafers could quickly loaded into the exposure inlet 34 or unloaded back to the idle and transport area 18 after the exposure process. In this embodiment, the exposure processing area 20 is directly connected to the idle and transport area 18, hence the wafers could be transported directly from the idle and transport area 18 to the exposure processing area 20 without the aid of other transporting equipment, such as an robot arm. The exposed wafers are transported from the exposure processing area 20 to the idle and transport area 18 and back to the coating and developing area 16 for the developing process.

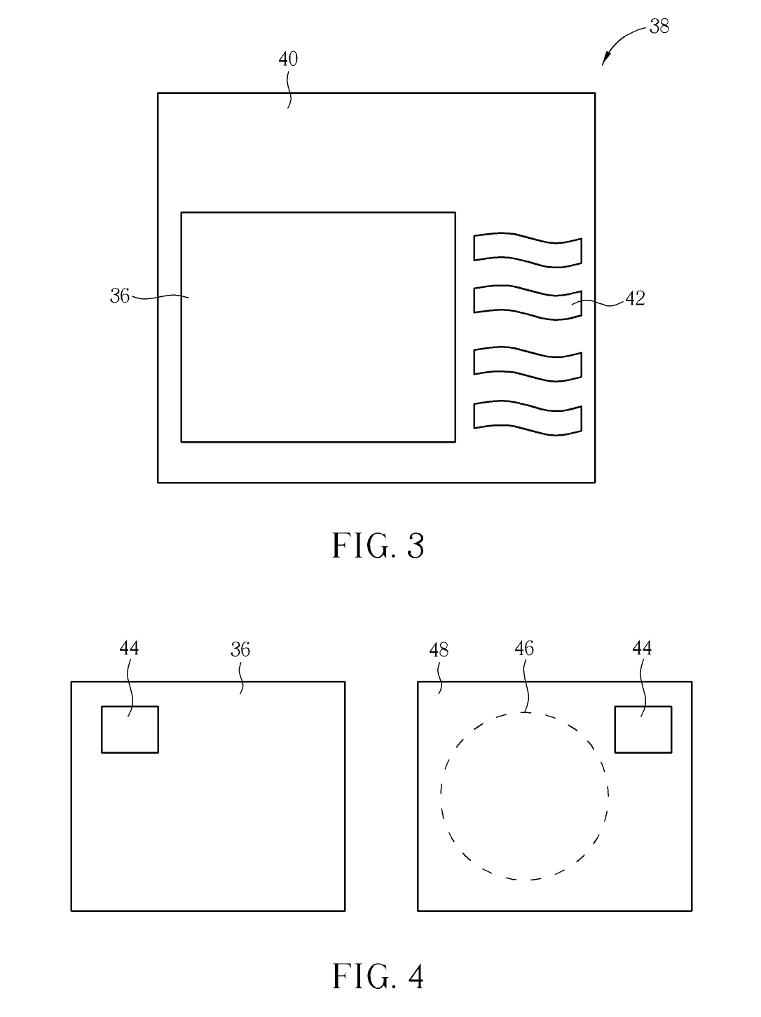

As shown in FIG. 3, a plurality of electronic racks 36 used for carrying electronic devices or functional modules is installed in the integrated lithography equipment 12. For illustration purpose, only one electronic rack 36 is revealed in the figure. These electronic devices are primarily circuit boards and wires used for controlling the lithography equipment, and could be distributed throughout the coating and developing area 16, the idle and transport area 18 and the exposure processing area 20 simultaneously. In order to protect wafers from the heat 42 caused by the aforementioned electronic devices or functional modules as the wafers are idled in the idle and transport area 18, an isolating system 38 is utilized to thermally isolate wafers from surrounding electronic devices or functional modules, or a heating/cooling system (not shown) is used to actively remove heat from the wafers and adjust the temperature of the wafers accordingly.

In order to thermally isolate the wafers from the surrounding heat sources, the present invention could use the isolating system 38 to completely enclose or partially shield the electronic rack 36 used for containing the heat radiating electronic devices or functional modules, or completely enclose or partially shield wafers or wafer cassettes carrying the wafers to thermally isolate the wafers. The isolating system 38 preferably includes a thermal shield 40 composed of aluminum foil, plastic or other thermal isolating material, but not limited thereto. The thermal shield 40 is preferably used to shield the plane between the electronic rack 36 containing circuit boards, devices, functional modules, or wires and the susceptible wafer, which effectively prevents the evaporation of solvents within the photoresist from the heat produced by these devices within the electronic rack 36 as the wafers are idled in the idle and transport area 18, and also prevents phenomenon such as expansion of the wafers. In addition, the thermal shield 40 composed of same or different thermal isolating material could also be used to enclose or partially shield the wafers or wafer cassettes containing the wafers, thereby prevention evaporation of solvents within the photoresist that have been previously coated on surface of the wafers. Despite the present embodiment preferably shield the plane between the electronic rack 36 and the susceptible wafer with the thermal shield 40 to ensure that the wafers are unaffected by the heat, the electronic rack 36 and the wafers or wafer cassettes could all be enclosed by the thermal shield 40 simultaneously or one of them is completely enclosed and the other one is partially shielded, which are also within the scope of the present invention. The shape or dimension of thermal shield 40 can be adjusted according to different coverage levels. For example, thermal shield 40 can be a plane thin film when it is used to shield the plane between the electronic rack 36 and the susceptible wafer, while it can have a shelled-shape when is it used to cover the electronic rack 36 or the susceptible wafer.

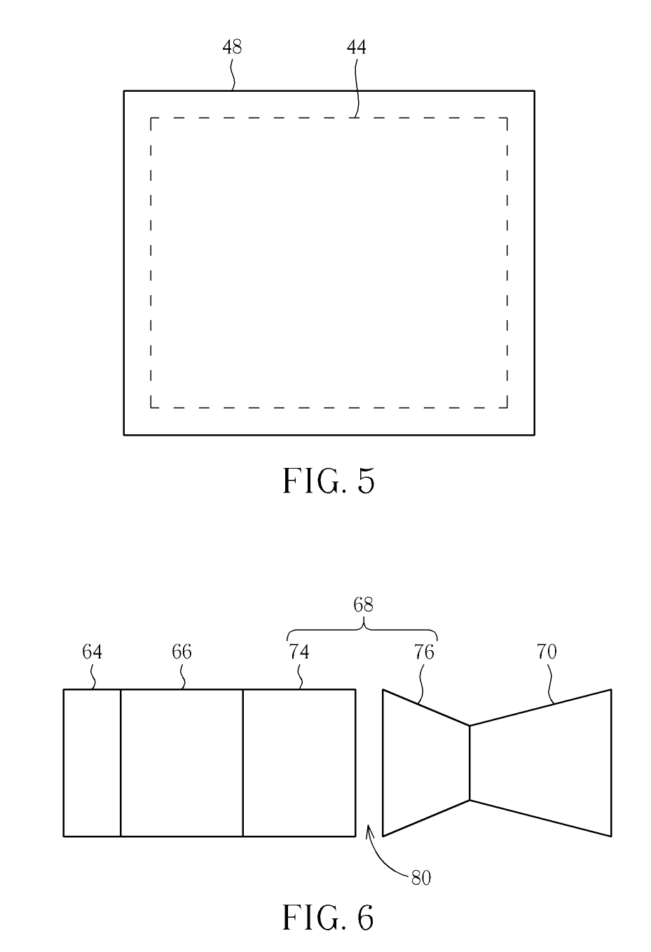

As shown in FIG. 4, in addition to the utilization of the thermal shield 40, a heating/cooling system 44 could be installed on the electronic rack 36 or on the wafer cassettes 48 carrying the wafer 46 to actively remove heat around the wafer 46 or within the wafer cassettes 48 thereby keeping the wafer 46 under a constant temperature. Depending on the demand of the fabrication, the heating/cooling system 44 could be composed of liquid or solid state heating/cooling system. In addition to actively remove heat around the wafer, the aforementioned heating/cooling system 44 could also be installed within the electronic rack 36 to expel excessive thermal energy created by the circuit board, functional modules and the wires. These two approaches of installing the heating/cooling system in this embodiment could be carried out individually or simultaneously, which are all within the scope of the present invention. For example, it is possible to use compressed air or air stream to blow the devices emitting heat within the electronic rack 36 and to use an air-removal device to remove the heated air; the same way can be implemented to the susceptible wafer. Additionally, as shown in FIG. 5, the heating/cooling system 44 could be a heat exchange system implemented by establishing liquid ducts on the wall of the wafer cassette 48 or electronic rack, such that the medium (either gas or liquid) used for heating or cooling could be applied through the wall of the cassettes 48 (or electronic rack) to either provide heat for wafer in the cassette 48 (or for modules in the electronic rack) or take away heat from the wafer in the cassette 48 (or from electronic device or module in the electronic rack).

Referring to FIG. 6, FIG. 6 illustrates a block diagram of an integrated lithography equipment according to another embodiment of the present invention. Similar to the above embodiment, the integrated lithography equipment of this embodiment includes an input/output area 64, a coating and developing area 66, an idle and transport area 68, and an exposure processing area 70. The input/output area 64 is positioned relative to the entrance of the integrated lithography equipment and this area 64 accommodates the wafers ready to be transported to the coating and developing area 66 or wafers that have already being processed through photolithography. The coating and developing area 66 is located right after the input/output area 64, which could include a plurality of tracks (not shown) for transporting the wafers. Wafers being transported from the input/output area 64 to the coating and developing area 66 will undergo a series of coating and soft baking processes.

The idle and transport area 68 is located between the coating and developing area 66 and the exposure processing area 70, and the idle and transport area 68 is preferably divided into a track idle area 74 and an exposure idle area 76. A wafer chuck (not shown) is disposed on the idle and transport area 68 for accommodating wafers ready to be transported into the exposure processing area 70 or transported out from the exposure processing area 70 for developing process. In this embodiment, a gap 80 is formed between the track idle area 74 and the exposure idle area 76. In other words, the track idle area 74 and the exposure idle area 76 are physically separated and as the wafers are idled in the track idle area 74, a robot arm, a transporting equipment, or manual transport is employed to transport wafers from the track idle area 76 to the exposure idle area 76, and later transported to the exposure processing area 70 for exposure process. Similarly, the robot arm, the transporting equipment, or manual transport would transport the wafers from the exposure idle area 76 back to the track idle area 74 after the exposure process is complete.

The aforementioned isolating system and heating/cooling system could also be incorporated in this embodiment to thermally isolate wafers from heat radiated by surrounding electronic devices or functional modules or actively remove heat from the wafers. For instance, a thermal shield composed of aluminum foil, plastic or other thermal isolating material could be used to enclose the electronic rack containing circuit boards, functional modules, other wires, or enclose the wafers directly, thereby preventing evaporation of solvents within the photoresists or expansion of the wafers. It should also be noted that as a robot arm is employed in this embodiment, the heating/cooling system could also be installed directly on the robot arm. By using the heating/cooling system installed on the robot arm to contact the wafers directly, the wafers could be maintained at a constant temperature.

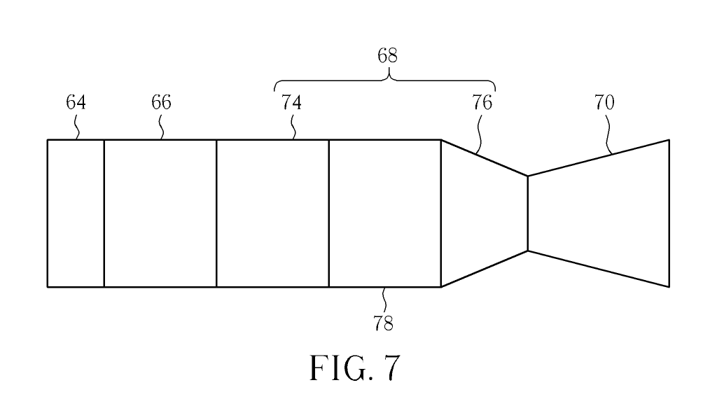

Referring to FIG. 7, FIG. 7 illustrates a block diagram of an integrated lithography equipment according to an embodiment of the present invention. Similar to the embodiment shown in FIG. 6, the integrated lithography equipment of this embodiment also includes an input/output area 64, a coating and developing area 66, an idle and transport area 68, and an exposure processing area 70. The idle and transport area 68 is preferably divided into a track idle area 74 and exposure idle area 76. It should be noted that a buffer area 78 is located between the track idle area 74 and the exposure idle area 76 for controlling the temperature of the wafer. For instance, the aforementioned isolating system or heating/cooling system could be employed in this buffer area 78 to isothermally or adiabatically transporting and holding wafers between the idle and transporting area 68 and the exposure processing area 78.

A lithography process is explained herein by referring back to FIGS. 1-2. First, a lithography equipment, such as an integrated lithography equipment 12 having an input/output area 14, a coating and developing area 16, an idle and transport area 18, and an exposure processing area 20 is provided. Wafers are then transported through tracks 22 from the input/output area 14 to the coating and developing area 16. Preferably, the wafers could be transported within wafer cassettes or directly on the tracks 22, which are all within the scope of the present invention. A photoresist is then coated onto the wafers through spin coating or atmospheric coating in the coating and developing area 16. Next, a pre-baking process is performed on the coated wafers to transform liquid-state photoresist into solid-state films thereby increasing the adhesion between the photoresist and surface of the wafer. The pre-baking process could be performed by means of hot air convection or irradiation of infrared lights, and the temperature is preferably controlled between 90° C. to 120° C.

The wafers are then transported to the idle and transport area 18 and a natural cooling process is performed on the wafers. It should be noted that an isolating system 38 or a heating/cooling system could be installed in the idle and transport area 18 and operators could utilize the isolating system 38 to thermally isolate wafers from heat caused by surrounding electronic devices or functional modules, or utilize the heating/cooling system to actively remove heat from the wafers such that the wafers could be maintained under a constant temperature.

The isolating system 38 could include a thermal shield 40 composed of aluminum foil, plastic or other thermal isolating materials, and the operators could cover the electronic rack 36 radiating heat with this thermal shield 40, which effectively prevents evaporation of solvents within the photoresists as the wafers are idled in the idle and transport area 18. Additionally, the thermal shield 40 could also be used to enclose the wafers themselves or even cassettes carrying the wafers, which are all within the scope of the present invention.

The heating/cooling system 44 could be installed in the electronic rack 36 or within the cassettes 48 carrying the wafers 46, thereby expelling heat around the wafer 46 and maintaining the wafer 46 under a constant temperature. Te heating/cooling system 44 could also be installed inside the electronic rack 36 for directing heat outward from the rack 36 so that evaporation of solvents within the coated photoresist or wafer deformation could be prevented. The above two approaches ensures that the wafers are transported isothermally and adiabatically between the idle and transport area 18 and the exposure processing area 20 and the wafers are also maintained under a constant temperature. According to a preferred embodiment of the present invention, the temperature is maintained at +/−5% of room temperature.

Next, the wafers are transported from the idle and transport area 18 to the exposure processing area 20. After an exposure is conducted in the exposure processing area 20, a clean dry air (CDA) process is performed by using a clean air gun to dry the surface of the wafers. A wafer measurement and wafer edge exclusion processes are then conducted and the processed wafers are transported back to the coating and developing area 16. A developing process is then performed to reveal the transferred pattern of the photoresist, and a hard baking process is conducted thereafter. The hard baking process is preferably conducted under a temperature between 100° C. to 130° C. to reduce the remaining solvents within the photoresist to a minimum amount thereby increasing the adhesion and selectivity of the photoresist for later processes. This completes the lithography process according to a preferred embodiment of the present invention.

Those skilled in the art will readily observe that numerous modifications and alterations of the device and method may be made while retaining the teachings of the invention.

What is claimed is:

1. An integrated lithography equipment, comprising:
an input/output area for loading or unloading at least one wafer;
a coating a developing area for performing coating and developing processes on the wafer;
an exposure processing area for exposing the wafer; and
an idle and transport area disposed between the coating and developing area and the exposure processing area for isothermally or adiabatically transferring wafers between the coating and developing area and the exposure processing area and holding wafers isothermally or adiabatically.

2. The integrated lithography equipment of claim 1, wherein the idle and transport area comprises an isolating system to thermally isolate wafers from other heat emitting devices.

3. The integrated lithography equipment of claim 2, wherein the isolating system comprises a thermal shield for at least shielding the plane between the other heat emitting devices and the wafers.

4. The integrated lithography equipment of claim 2, wherein the isolating system comprises a thermal shield for covering the wafers.

5. The integrated lithography equipment of claim 1, wherein the idle and transport area comprises a heating/cooling system to stabilize the temperature of the wafers.

6. The integrated lithography equipment of claim 1, wherein the idle and transport area comprises a heating/cooling system to stabilize the temperature of other heat emitting devices.

7. The integrated lithography equipment of claim 1, further comprising a gap between the coating and developing area and the exposure processing area.

8. The integrated lithography equipment of claim 7, further comprising at least one wafer cassette accommodating the wafers, wherein the wafer cassette comprises a heating/cooling system.

9. A lithography process, comprising:
providing a wafer;
performing a first process to the wafer in a first processing area to obtain a processed wafer; and
idling or transporting the processed wafer isothermally or adiabatically in an idle and transport area to a second processing area for a second process.

10. The lithography process of claim 9, wherein the first process is a coating or developing process and the second process is an exposure process.

11. The lithography process of claim 9, wherein the first process is an exposure process and the second process is a coating or developing process.

12. The lithography process of claim 9, wherein the idle and transport area comprises an isolating system to thermally isolate wafers from other heat emitting devices.

13. The lithography process of claim 12, wherein the isolating system comprises a thermal shield for covering the processed wafer.

14. The lithography process of claim 12, wherein the isolating system comprises a thermal shield for at least shielding the plane between the other heat emitting devices and the processed wafer.

15. The lithography process of claim 9, wherein the idle and transport area comprises a heating/cooling system to stabilize the temperature of the processed wafer.

16. The lithography process of claim 9, wherein the idle and transport area comprises a heating/cooling system to stabilize the temperature of other heat emitting devices.

17. The lithography process of claim 9, further comprising a gap between the first processing area and the second processing area.
